(19) United States
(12) Patent Application Publication
(10) Pub. No.: US 2025/0160182 A1
(43) Pub. Date: May 15, 2025

(54) Light Emitting Display Device

(71) Applicant: LG Display Co., Ltd., Seoul (KR)

(72) Inventors: Yeonsuk Kang, Paju-si (KR); Cheolhwan Lee, Paju-si (KR); Chanwook Choi, Paju-si (KR)

(21) Appl. No.: 18/812,294

(22) Filed: Aug. 22, 2024

(30) Foreign Application Priority Data
Nov. 13, 2023 (KR) 10-2023-0156800

(51) Int. Cl. H10K 59/80; H10K 59/122; H10K 59/38

(52) U.S. Cl. CPC H10K 59/879; H10K 59/122; H10K 59/38; H10K 59/873; H10K 59/8792

(57) ABSTRACT

A light emitting display device comprises: a substrate including a display area and a non-display area; a plurality of pixels in the display area; a lens processing pattern in the non-display area and surrounding the display area; a light emitting element layer in the display area; an encapsulation layer on the light emitting element layer in the display area; and a color filter layer and a lens layer on the encapsulation layer in the display area. An upper surface of the lens processing pattern is a same as a height of an upper surface of the lens layer.

### CROSS-REFERENCE TO RELATED APPLICATION

This application claims the benefit of the Republic of Korea Patent Application No. 10-2023-0156800 filed on Nov. 13, 2023, which is hereby incorporated by reference in its entirety.

### BACKGROUND

### Field of Technology

The present disclosure relates to a light emitting display device.

### Discussion of the Related Art

Recently, a head mount display (HMD) including an organic light emitting diode display has been developed. The HMD is a wearable monitor device for virtual reality (VR) or augmented reality (AR) that is worn in the form of glasses or a helmet so it focuses on a distance close to the user's eyes. Such a head-mounted display may be equipped with a small organic light emitting diode display with high resolution property.

Particularly, in an ultra-high-density resolution display device having a pixel density of 4K (ppi: pixel per inch) or more, since the gaps between pixels is very narrow, color mixing may be occurred between two neighboring pixels, causing deterioration in image quality. Further, since the size of the pixel is very small, the structural improvement for improving light efficiency is required to provide a brighter and clearer image quality with the same power consumption.

### SUMMARY

The purpose of the present disclosure, as for solving the problems described above, is to provide a top emission type light emitting display device or a top emission type transparent light emitting display device having high luminance compared to power consumption.

One or more example embodiments of the present disclosure may provide a top emission type light emitting display device or a top emission type transparent light emitting display device equipped with a structure to prevent color mixing or light leakage between the pixels configuring the light emitting diode.

One or more example embodiments of the present disclosure may be directed to providing a top emission type light emitting display device or a top emission type transparent light emitting display device capable of low power driving with higher luminance with the same power consumption by including a lens layer having a structure capable of improving light efficiency.

One or more example embodiments of the present disclosure may be directed to providing a top emission type light emitting display device or a top emission type transparent light emitting display device minimizes or at least reduces light loss by concentrating the light provided by the light emitting layer and has an even luminance distribution, by placing a micro lens with a flat part in the central portions and a curved part at the edge portions.

In order to accomplish the above mentioned purposes of the present disclosure, a light emitting display device according to the present disclosure comprises a light emitting display device comprising: a substrate including a display area and a non-display area; a plurality of pixels in the display area; a lens processing pattern in the non-display area, the lens processing pattern surrounding the display area; a light emitting element layer in the display area, the light emitting element layer configured to emit light; an encapsulation layer on the light emitting element layer in the display area; and a color filter layer and a lens layer on the encapsulation layer in the display area, wherein a height of an upper surface of the lens processing pattern is a same as a height as an upper surface of the lens layer.

In one embodiment, a display device comprises: a substrate including a display area and a non-display area; a transistor on the display area of the substrate; a planarization layer on the display area and the non-display area, the planarization layer on the transistor in the display area; a light emitting element configured to emit light in an emission area of the light emitting element, the light emitting element on the planarization layer and connected to the transistor; an encapsulation layer on the light emitting element in the display area; a color filter overlapping the emission area of the light emitting element; and a lens overlapping the color filter and the emission area of the light emitting element, the lens having a flat upper surface and a curved side surface that extends from the flat upper surface.

The light emitting display device according to the present disclosure may have a structure for ensuring the front light concentrating by arranging a micro lens layer, so that light extraction efficiency may be enhance or maximized. Even in an ultra-high density resolution display device having very small size of the emission area, higher luminance may be provided with the same power consumption. Accordingly, the low power driving may be implemented.

The light emitting display device according to the present disclosure may be provided with a micro lens having a flat surface in the central portion and a curved surface in the edge portion. In addition, a black matrix may be disposed between the micro lenses corresponding to the curved surface. Therefore, light may be not excessively concentrated in the central portion, and luminance may be evenly distributed in the pixel area. Further, due to the black matrix, color mixing may not occur between neighboring pixels even in ultra-high-resolution display devices where the spacing between pixels is narrowed.

The light emitting display device according to the present disclosure may have lens processing pattern in the non-display area. By forming the height of the upper surface of the lens processing pattern to match the height of the flat surface of the micro lens, a micro lens with a uniform height may be proved by a compression method using the lens processing pattern.

In addition to the effects of the present disclosure mentioned above, other features and advantages of the present disclosure are described below, or may be clearly understood by those skilled in the art from such descriptions and explanations.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plane view illustrating a schematic structure of a light emitting display device according to an embodiment of the present disclosure.

FIG. 2 is a circuit diagram illustrating a structure of one pixel disposed in a light emitting display device according to an embodiment of the present disclosure.

FIG. 3 is an enlarged plan view illustrating a structure of three pixels sequentially disposed in the light emitting display device according to an embodiment of the present disclosure.

FIG. 4 is a cross-sectional view, cutting along line I-I′ in FIG. 3, for illustrating a structure of one pixel in a light emitting display device according to an embodiment of the present disclosure.

FIG. 5 is a cross-sectional view, cutting along line II-II′ in FIG. 3, for illustrating a structure of three pixels sequentially arrayed in a light emitting display device according to a first embodiment of the present disclosure.

FIG. 6 is an enlarged cross-sectional view, cutting along line II-II′ of FIG. 3, for illustrating a structure of three pixels sequentially arrayed in a light emitting display device according to a second embodiment of the present disclosure.

FIG. 7 is an enlarged cross-sectional view, cutting along line II-II′ of FIG. 3, for illustrating a structure of three pixels sequentially arrayed in a light emitting display device according to a third embodiment of the present disclosure.

FIG. 8 is an enlarged cross-sectional view, cutting along line II-II′ of FIG. 3, for illustrating a structure of three pixels sequentially arrayed in a light emitting display device according to a fourth embodiment of the present disclosure.

FIG. 9 is an enlarged cross-sectional view, cutting along line II-II′ of FIG. 3, for illustrating a structure of three pixels sequentially arrayed in a light emitting display device according to a fifth embodiment of the present disclosure.

FIG. 10 is an enlarged cross-sectional view, cutting along line III-III′ of FIG. 1, for illustrating a portion where the lens processing pattern is formed in a light emitting display device according to one or more embodiments of the present disclosure.

FIG. 11 is an enlarged cross-sectional view, enlarging ‘A’ portion of FIG. 1, for illustrating an example embodiment of the lens processing pattern in one or more embodiments of the present disclosure.

FIG. 12 is an enlarged cross-sectional view, enlarging ‘A’ portion of FIG. 1, for illustrating another example embodiment of the lens processing pattern in one or more embodiments of the present disclosure.

FIG. 13 is an enlarged cross-sectional view, enlarging ‘A’ portion of FIG. 1, for illustrating still another example embodiment of the lens processing pattern in one or more embodiments of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate (ly),” “direct (ly),” or “close (ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate (ly),” or “direct (ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts.

Hereinafter, referring to the attached figures, the present disclosure will be explained. Since a scale of each of elements shown in the accompanying drawings may be different from an actual scale for convenience of description, the present disclosure is not limited to the scale shown in the drawings.

FIG. 1 is a plane view illustrating a schematic structure of a light emitting display device according to an embodiment of the present disclosure. In FIG. 1, X-axis refers to the direction parallel to the scan line, Y-axis refers to the direction of the data line, and Z-axis refers to the height direction of the display device.

Referring to FIG. 1, the electroluminescence display comprises a substrate 110, a gate (or scan) driver 200, a pad portion 300, a source driving IC (integrated circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of pixels P are arrayed in a matrix manner. Further, a plurality of scan lines (or gate lines), a plurality of data lines may be disposed as crossing each other. Each of pixels P may be disposed at the crossing area of the scan line running to X-axis and the data line running to Y-axis.

Here, the pixel P may represent any one of color among red, green and blue or red, green, blue or white. A red pixel, a green pixel and a blue pixel may be gathered or a red pixel, a green pixel, a blue pixel and a white pixel may be gathered to form one unit pixel. For example, each of the pixels representing each color may be called as a ‘sub-pixel’, and it may be explained that these ‘sub-pixels’ form one ‘pixel’. As another example, it may be explained that pixels P representing each color are called as ‘pixels’, and three or four of these ‘pixels’ are gathered to form one ‘unit pixel’. Hereinafter, the latter case will be described.

The non-display area NDA, which is an area not representing the video images, may be defined at the circumference areas of the substrate 110 surrounding all or some of the display area AA. In the non-display area NDA, the gate driver 200 and the pad portion 300 may be formed or disposed. Further, a lens processing pattern 1000 may be disposed in the non-display area NDA.

The gate driver 200 may supply the scan (or gate) signals to the scan lines SL according to the gate control signal received from the timing controller 500 through the pad portion 300. The gate driver 200 may be formed at the non-display area NDA at any one outside of the display area DA on the substrate 110, as a GIP (Gate driver In Panel) type. GIP type means that the gate driver 200 is directly formed on the substrate 110. For example, the gate driver 200 may be configured with shift registers. In the GIP type, the transistors for shift registers of the gate driver 200 are directly formed on the upper surface of the substrate 110.

The pad portion 300 may be disposed in the non-display area NDA at one side edge of the display area AA of the substrate 110. The pad portion 300 may include data pads connected to each of the data lines DL, driving current pads connected to the driving current lines, a high-potential pad receiving a high potential voltage, and a low-potential pad receiving a low potential voltage.

The lens processing pattern 1000 may be disposed at the outermost area of the non-display area NDA. For an example, the lens processing pattern 1000 may have a rectangular ring shape surrounding the display area AA and the gate driver 200 excepting the pad portion 300 in a plan view of the display device. However, the embodiment of the present disclosure is not limited thereto, the lens preparing pattern 1000 may be disposed between the display area AA and the gate driver 200. Otherwise, the lens processing pattern 1000 may be disposed as overlapping with the gate driver 200.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be integrated with the source driving IC 410 into one driving chip and may be mounted on the substrate 110 to be connected to the pad unit 300.

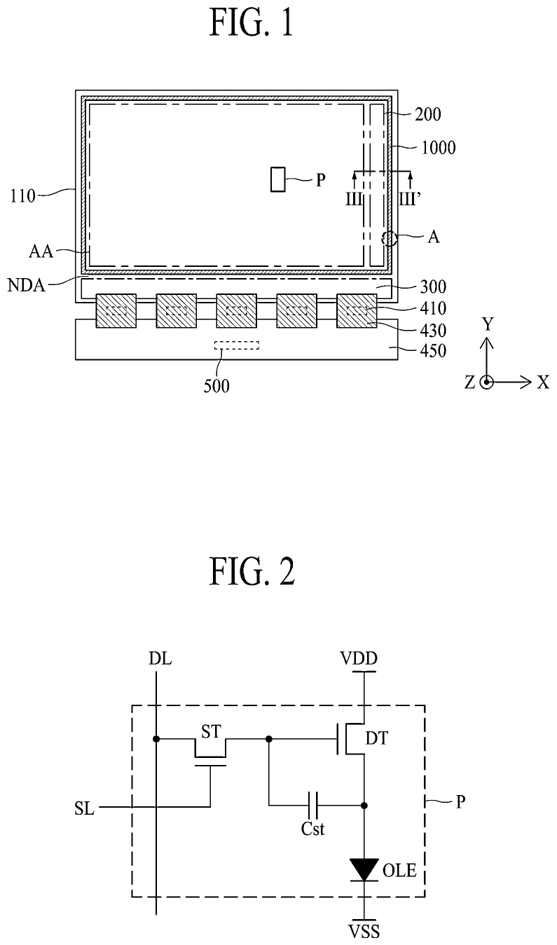

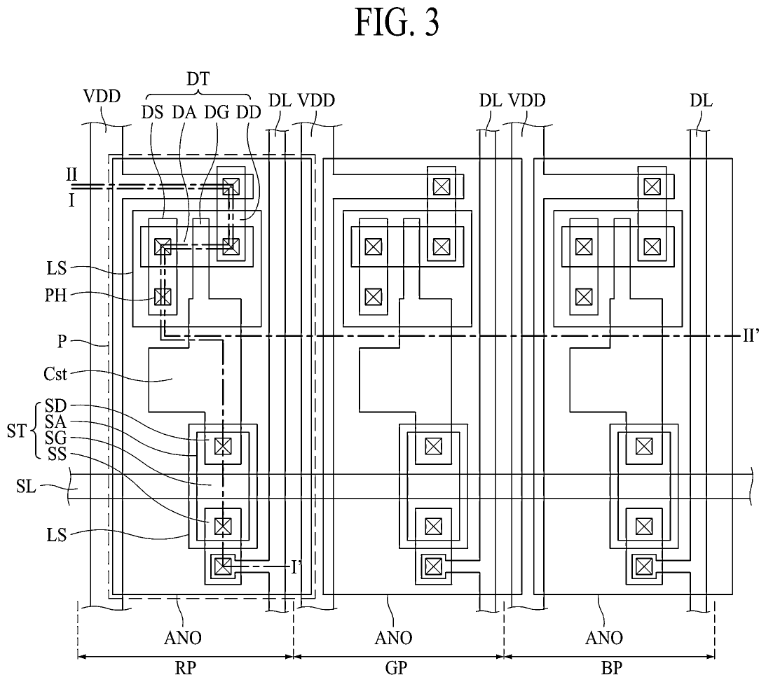

Hereinafter, referring to FIGS. 2 to 4, a detailed structure of a light emitting display device according to an embodiment of the present disclosure will be explained. FIG. 2 is a circuit diagram illustrating a structure of one pixel disposed in a light emitting display device according to an embodiment of the present disclosure. FIG. 3 is an enlarged plan view illustrating a structure of three pixels sequentially disposed in the light emitting display device according to an embodiment of the present disclosure.

Referring to FIGS. 2 to 3, each pixel P of the light emitting display according to the present disclosure may be defined by a scan line SL, a data line DL and a driving current line VDD. Each pixel P of the light emitting display may include a switching thin film transistor ST, a driving thin film transistor DT, a light emitting diode OLE and a storage capacitance (or capacitor) Cst. The driving current line VDD may be supplied with a high-level voltage for driving the light emitting diode OLE.

A switching thin film transistor ST and a driving thin film transistor DT may be formed on a substrate 110. For example, the switching thin film transistor ST may be configured to be connected to the scan line SL and the data line DL is crossing. The switching thin film transistor ST may include a gate electrode SG, a semiconductor layer SA, a source electrode SS and a drain electrode SD. The gate electrode SG may be a portion of the scan line SL. The semiconductor layer SA may be disposed as crossing the gate electrode SG. The overlapped portion of the semiconductor layer SA with the gate electrode SG may be defined as the channel area. The source electrode SS may be branched from or connected to the data line DL, and the drain electrode SD may be connected to the driving thin film transistor DT. The source electrode SS may be one side of the semiconductor layer SA from the channel area, and the drain electrode SD may be the other side of the semiconductor layer SA. By supplying the data signal to the driving thin film transistor DT, the switching thin film transistor ST may play a role of selecting a pixel P which would be driven.

The driving thin film transistor DT may play a role of driving the light diode OLE of the selected pixel P by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be extended form the drain electrode SD of the switching thin film transistor ST. In the driving thin film transistor DT, the drain electrode DD may be branched from or connected to the driving current line VDD, further, the source electrode DS may be connected to the anode electrode (or pixel electrode) ANO of the light emitting diode (or light emitting element) OLE. The semiconductor layer DA may be disposed as crossing over the gate electrode DG. In the semiconductor layer DA, the overlapped portion with the gate electrode DG may be defined as a channel area. The source electrode DS may be connected at one side of the semiconductor layer DA around the channel area, and the drain electrode DD is connected to the other side of the semiconductor layer DA. A storage capacitance (or, capacitor) Cst may be disposed between the gate electrode DG of the driving thin film transistor DT and the anode electrode ANO of the light emitting diode OLE.

The light emitting diode OLE may generate light according to the current controlled by the driving thin film transistor DT. The driving thin film transistor DT may control the amount of current flowing from the driving current ling VDD to the light emitting diode OLE according to the voltage difference between the gate electrode DG and the source electrode DS.

The light emitting diode OLE may include an anode electrode ANO, an emission layer EL, and a cathode electrode CAT. The light emitting diode OLE may emit lights according to the current controlled by the driving thin film transistor DT. In other words, the light emitting diode OLE may provide an image by emitting light according to the current controlled by the driving thin film transistor DT. The anode electrode ANO of the light emitting diode OLE may be connected to the source electrode DS of the driving thin film transistor DT. The cathode electrode CAT (or, common electrode) may be low-power line VSS supplied with the low-potential voltage. Therefore, the light emitting diode OLE may be driven by the electric current flown from the driving current line VDD to the low power line VSS controlled by the driving thin film transistor DT.

A plurality of pixels P may be arrayed on the substrate 110. For example, along the horizontal direction, a red pixel RP, a green pixel GP and a blue pixel BP may be sequentially arrayed and disposed. The combination of the red pixel RP, the green pixel GP and the blue pixel BP may configure one pixel. In another case, the red pixel, the green pixel, the white pixel and the blue pixel may be sequentially arrayed along the horizontal direction. The red pixel, the green pixel, the white pixel and the blue pixel may form a unit pixel. FIG. 3 shows that three pixels P, including a red pixel RP, a green pixel GP and a blue pixel BP, sequentially are arrayed along the horizontal direction.

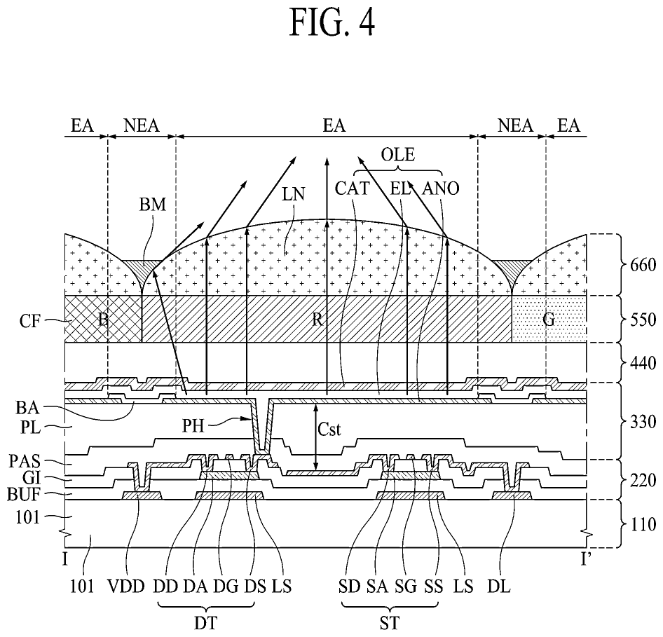

Referring to FIG. 4, a cross-sectional structure of the light emitting display device according to an embodiment of the present disclosure will be explained. FIG. 4 is a cross-sectional view along to cutting line I-I′ in FIG. 3, for illustrating a structure of one pixel in a light emitting display device according to an embodiment of the present disclosure. A light emitting display device may include a substrate 110, a driving element layer 220, a light emitting element layer 330, an encapsulation layer 440, a color filter layer CF and a lens layer 660. The driving element layer 220 may include a plurality of thin layers formed on the substrate 110. The driving element layer 220 may include a switching thin film transistor ST and a driving thin film transistor DT.

On the substrate 110, a data line DL, a driving current line VDD and a light shielding layer LS may be formed. The light shielding layer LS may be disposed in an island shape spaced apart from the data line DL and the driving current line VDD by a predetermined distance and overlapping the semiconductor layers SA and DA. In some cases, the light shielding layer LS may be omitted.

A buffer layer BUF is deposited on entire surface of the substrate 110 as covering the data line DL and the driving current line VDD. On the buffer layer BUF, the semiconductor layer SA of the switching thin film transistor ST and the semiconductor layer DA of the driving thin film transistor DT are formed. The switching thin film transistor ST and the driving thin film transistor DT are formed on the buffer layer BUF. It is preferable that the channel areas in the semiconductor layers SA and DA overlap with the light shielding layer LS.

A gate insulating layer GI is deposited on the substrate 110 as covering the semiconductor layers SA and DA. A gate electrode SG overlapping with the semiconductor layer SA of the switching thin film transistor ST and the gate electrode DG overlapping with the semiconductor layer DA of the driving thin film transistor DT are formed on the gate insulating layer GI. In addition, at both sides of the gate electrode SG of the switching thin film transistor ST, a source electrode SS contacting one side of the semiconductor layer SA while being spaced apart from the gate electrode SG, and a drain electrode SD contacting the other side of the semiconductor layer SA, while being spaced apart from the gate electrode SG, are formed. Further, at both sides of the gate electrode DG of the driving thin film transistor DT, a source electrode DS contacting one side of the semiconductor layer DA while being spaced apart from the gate electrode DG, and a drain electrode DD contacting the other side of the semiconductor layer DA, while being spaced apart from the gate electrode DG, are formed.

The gate electrodes SG and DG and the source-drain electrodes SS-SD and DS-DD are formed on the same layer, but are spatially and electrically separated from each other. The source electrode SS of the switching thin film transistor ST may be connected to the data line DL via a contact hole penetrating the gate insulating layer GI. Further, the drain electrode DD of the driving thin film transistor DT may be connected to the driving current line VDD via another contact hole penetrating the gate insulating layer GI.

A passivation layer PAS is deposited on the substrate 110 as covering the thin film transistors ST and DT. The passivation layer PAS may be made of an inorganic material such as silicon oxide or silicon nitride.

The light emitting element layer 330 is formed on the driving element layer 220. The light emitting element layer 330 may include a planarization layer PL and a light emitting diode OLE. The planarization layer PL may be a layer covering the substrate 110 and used to flatten the uneven surface of the substrate 110 on which the thin film transistors ST and DT are formed. In order to equalize or compensate the height difference due to the uneven surface condition, the planarization layer PL may be formed of an organic material. A pixel contact hole PH may be formed at the passivation layer PAS and the planarization layer PL to expose a portion of the source electrode DS of the driving thin film transistor DT.

An anode electrode (or, pixel electrode) ANO may be formed on the top surface of the planarization layer PL. The anode electrode ANO may be connected to the source electrode DS of the driving thin film transistor DT via a pixel contact hole PH. The anode electrode ANO may have different structure and configuring elements according to the emission type of the light emitting diode OLE. For example, in the case of a bottom emission type that provides lights in the downward direction towards the substrate 110, it may be formed of a transparent conductive material. For another example, in the case of a top emission type that provides lights in the upward direction opposite to the substrate 110, it may be formed of a metal material having excellent light reflectance. Alternatively, for the case of top emission type that provides light in the upward direction opposite to the substrate 110, a reflective layer formed of a metal material with excellent light reflectance may be further included below or above the transparent layer formed of a transparent conductive material.

A bank BA is formed on the top surface of the substrate 110 having the anode electrode ANO. In one embodiment, the bank BA is an insulating layer made of an inorganic material or an organic material. Hereinafter, a case made of an in organic material will be described. The bank BA covers the circumferential areas of the anode electrode ANO, and exposes most of the middle area. The middle area exposed from the bank BA is defined as an emission area EA, and the area covered by bank BA is defined as a non-emission area NEA.

An emission layer EL is disposed on the anode electrode ANO and bank BA. The emission layer EL may be deposited on entire of the display area AA of the substrate 110 as covering the anode electrode ANO and the bank BA. For an example, the emission layer EL may include at least two emission parts for generating white light. In detail, the emission layer EL may include a first emission part and a second emission part vertically stacked for generating white light by mixing the first light from the first emission part and the second light from the second emission part.

For another example, the emission layer EL may include any one of a blue emission part, a green emission part, and a red emission part for generating light corresponding to a color set in each pixel. Further, the light emitting diode OLE may include a functional layer for improving light emitting efficiency and/or lifetime of the emission layer EL.

A cathode electrode (or common electrode) CAT is deposited on the entire surface of the substrate 110 on which the emission layer is formed. The cathode electrode CAT is deposited to make surface contact with the emission layer EL. The cathode electrode CAT is formed over the entire substrate 110 to be commonly connected to the emission layer EL deposited in all pixels. In the case of the top emission type, the cathode electrode CAT may include a transparent conductive material. For example, the cathode electrode CAT may be made of a transparent conductive material such as indium-tin-oxide (ITO) or indium-zinc-oxide (IZO). Alternatively, the cathode electrode CAT may include a thin metal such as aluminum (Al), magnesium (Mg), calcium (Ca), silver (Ag) or an alloy or combination thereof (e.g., aluminum-magnesium alloy (AlMg)). It may be formed to have light-transmitting characteristics by forming it with a thin thickness in a range of 20 Å to 300 Å. For the case of bottom emission type, the cathode electrode CAT may be made of a metal material having excellent light reflectance with 2,000 Å or more thickness. The metal material having excellent light reflectance may include any one of aluminum (Al), magnesium (Mg), calcium (Ca), silver (Ag) or an alloy or combination thereof (e.g., aluminum-magnesium alloy (AlMg)).

An encapsulation layer 440 is stacked on the light emitting element layer 330. The encapsulation layer 440 may have a single-layer structure made of an inorganic material, or a multi-layer structure in which several inorganic layers are sequentially stacked. As another example, the encapsulation layer 440 may have a structure in which an inorganic layer, an organic layer and an inorganic layer are continuously stacked. Here, for convenience of description, the encapsulation layer 440 made of a single inorganic layer will be used for explanation.

A color filter layer 550 is stacked on the encapsulation layer 440. The color filter layer 550 includes a plurality of color filters CF that are arranged in a matrix manner to correspond to the arrangement of the pixels P. The color filter CF may be disposed with a structure in which one of a red color filter, a green color filter and a blue color filter is assigned to each pixel P. As another example, the color filter CF may be disposed with a structure in which one of a red color filter, a white color filter, a green color filter and a blue color filter is allocated to each pixel P. Hereinafter, for convenience of description, a case, in which the color filter CF includes a red color filter R, a green color filter G and a blue color filter B, is used for explanation.

A lens layer 660 may be disposed on the color filter layer 550. The lens layer 660 may include a plurality of micro lenses LN. Each of micro lenses LN may be formed as being corresponding to each of pixels P. For example, one micro lens LN may be formed in a shape of a hemispherical (or semi-circular) convex lens on the red color filter R such that the micro lens LN overlaps the red color filter R. A black matrix BM may be disposed between a neighboring pair of micro lenses LN. The black matrix BM may be disposed at a position corresponding to the bank BA of the light emitting element layer 330. That is, the black matrix BM overlaps the bank BA. For an example, the black matrix BM may have a size equal to or slightly smaller than the bank BA and may be arranged to correspond to the center of the bank BA.

In the case that the micro lens LN has a hemispherical or semi-elliptical shape, as shown by the arrows in FIG. 4, the light provided from the emission layer EL may be directed (i.e., concentrated) to the center of the emission area EA of the pixel P due to the light-concentrating function of the micro lens LN. Especially, light that may be lost by going to the black matrix BM may be refracted from the curved surface of the micro lens LN to the central portion, thereby reducing light loss.

As the result, the luminance of the central portion of the pixel P may be increased. However, when it is excessively concentrated at the central portion, the luminance distribution may not be uniform throughout the entire emission area EA of the pixel P. In this case, the frontal luminance may be very high, but the luminance in the wide viewing angle direction may be decreased, which may cause problems such as overall image quality deterioration or uneven luminance.

Hereinafter, a structure for preventing light provided from the emission layer EL by the micro lens LN from being excessively concentrated in the central portion will be described through various embodiments of the present disclosure. According to the following embodiments, the present disclosure may provide light emitting display devices having a structure that may uniformly improve the frontal luminance and wide viewing angel luminance while minimizing loss of the light provided from a pixel.

### First Embodiment

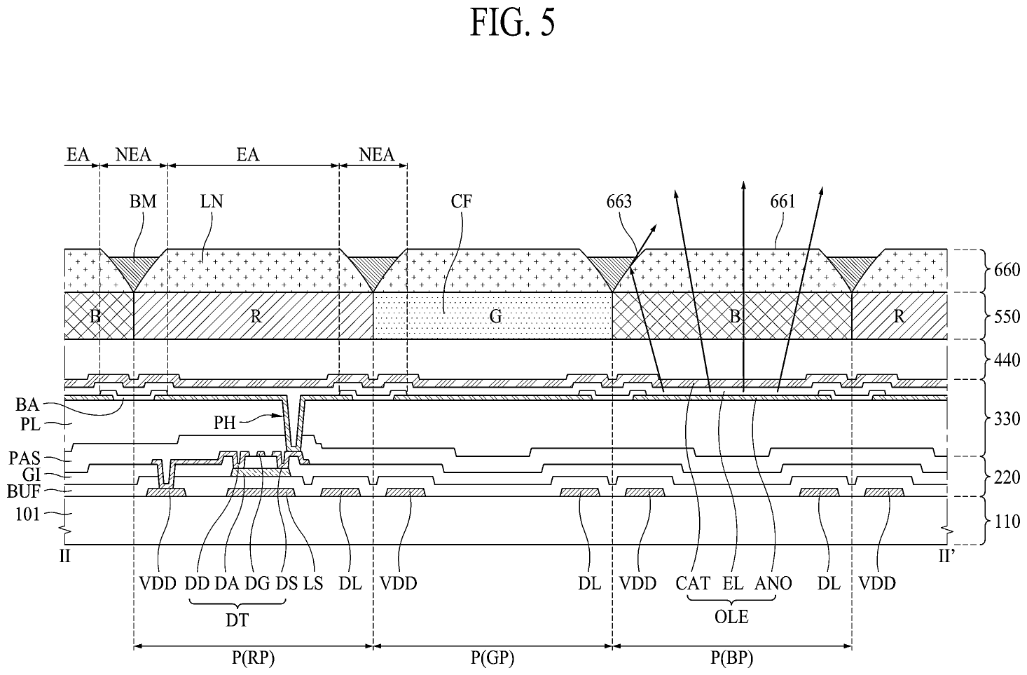

Referring to FIG. 5, a first embodiment of the present disclosure will be explained. FIG. 5 is a cross-sectional view, cutting along line II-II′ in FIG. 3, for illustrating a structure of three pixels sequentially arrayed in a light emitting display device according to a first embodiment of the present disclosure.

A light emitting display device according to the first embodiment of the present disclosure may comprise the substrate 110, the driving element layer 220, the light emitting element layer 330, the encapsulation layer 440, the color filter layer 550 and the lens layer 660. The elements below the encapsulation layer 440 in FIG. 5 may be same as that described in FIG. 4, so detailed descriptions may be omitted.

Referring to FIG. 5, the color filter layer 550 may be disposed on the encapsulation layer 440. The color filter layer 550 may include a plurality of color filters CF. For an example, the color filter layer 550 may include a red color filter R, a green color filter G and a blue color filter B. The red color filter R may be disposed at the red pixel RP, the green color filter G may be disposed at the green pixel GP, and the blue color filter B may be disposed at the blue pixel BP.

The lens layer 660 may be disposed on the color filter layer 550. The lens layer 660 may include a plurality of micro lenses LN and a black matrix BM between neighboring micro lenses LN. One micro lens LN may be arranged in one-to-one correspondence with one pixel P. The micro lens LN may be configured to have a flat surface (or flat portion or flat upper surface) 661 at central area and a curved surface (or curved portion or curved side surface) 663 at edge area surrounding the flat surface. The flat surface 661 may be disposed to correspond to (e.g., overlap) the anode electrode ANO. The flat surface 661 may have a size that is slightly larger or smaller than the anode electrode ANO. In some cases, the flat surface 661 may have the same size as the anode electrode ANO.

The curved surface 663 is an area corresponding to an edge area of the hemispherical micro lens LN shown in FIG. 4, and may be arranged to correspond to the bank BA. In one micro lens LN, the curved surface 663 may correspond to half size of the bank BA. At an area where two neighboring micro lenses LN meet, the curved surface 663 of each of the two micro lenses LN may be disposed to correspond to the bank BA.

At an area where a pair of neighboring micro lenses LN meet, two curved surfaces 663 may be configured to have a wedge shape or valley shape, such as a ‘V’ shape that is between the pair of neighboring micro lenses LN. The black matrix BM may be disposed at the wedge shape (or valley shape). The black matrix BM may be arranged to correspond to the bank BA. The black matrix BM may have a size that is slightly larger or smaller than the bank BA. In one embodiment, the black matrix BM may have a slightly smaller size than the bank BA and is arranged to overlap the inside of the bank BA. The black matrix BM may prevent or reduce color mixing between two neighboring pixels P. For example, the black matrix BM disposed between the red pixel PR and the green pixel PG may be prevent or reduce the light generated from the red pixel PR from entering into the green pixel PG, or the light generated from the green pixel PG from entering into the red pixel PR.

The light emitting display device according to the first embodiment may have a structure in which the plurality of micro lenses LN may be arranged one-to-one corresponding to the pixels P. Accordingly, the light provided from the emission layer EL of each pixel P may be concentrated to the central area of the pixel P by the micro lens LN, thereby improving light emission efficiency. In addition, the micro lens LN of the light emitting display device according to the first embodiment may include the flat surface 661 at the central area. At the flat surface 661, the light provided by the emission layer EL may be not excessively concentrated in the central area, and may be emitted while maintaining the viewing angle provided by the emission layer. The curved surface 663 may be provided at the edge of the flat surface 661 as surrounding the flat surface 661. The curved surface 663 may allow the light provided from the emission layer EL to be concentrated in the central area without being absorbed by and lost in the black matrix BM disposed at the edge area of the pixel P.

Accordingly, the loss of light from each pixel P may be minimized or at least reduced. In addition, the light emitting display device according to the first embodiment may provide uniform luminance within a wide viewing angle range. As the result, it is possible to provide a display device that recovers the lost light to the central area, provides a high luminance with low power consumption, and has luminance distribution uniformly over the entire area of the display device substrate.

### Second Embodiment

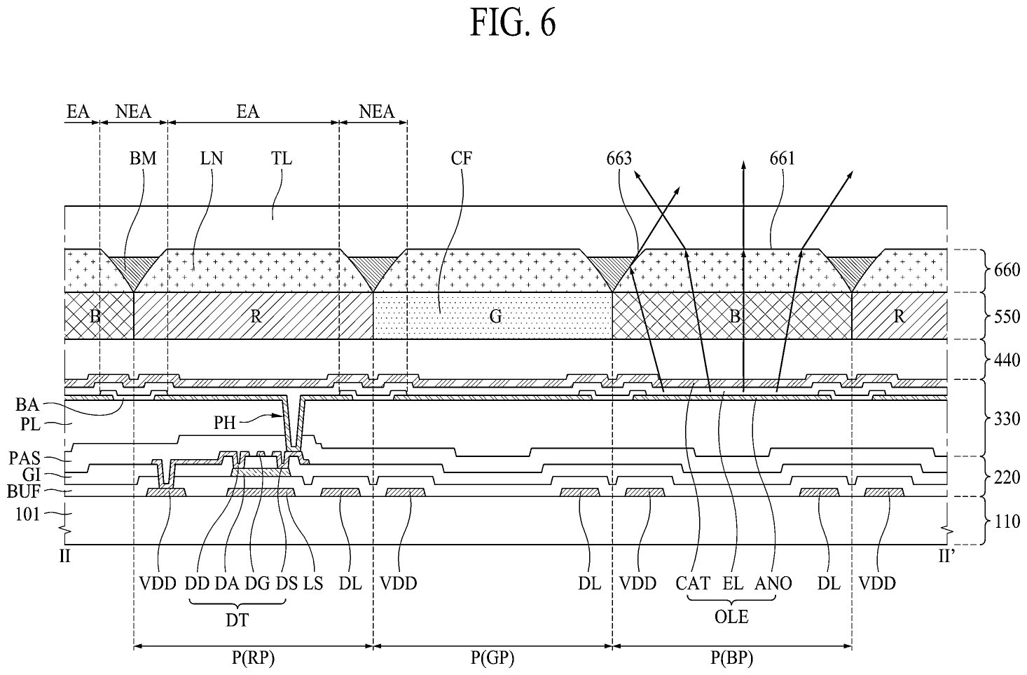

Hereinafter, referring to FIG. 6, a structure of a light emitting display device according to a second embodiment of the present disclosure will be explained. FIG. 6 is an enlarged cross-sectional view, cutting along line II-II′ of FIG. 3, for illustrating a structure of three pixels sequentially arrayed in a light emitting display device according to a second embodiment of the present disclosure.

A light emitting display device according to a second embodiment of the present disclosure as shown in FIG. 6 may have very similar structure as that of the first embodiment. The difference is that a top layer TL is disposed on an upper surface of the lens layer 660 in the second embodiment. The elements same with the first embodiment may not be duplicately explained.

The top layer TL may be disposed over entire surface of the substrate 110 on the lens layer 660 including the micro lenses LN and the black matrix BM. The top layer TL may be an element for protecting the lens layer 660. In addition, the top layer TL may be made of a transparent material having refractive index different from the micro lens LN in one embodiment.

In particular, the top layer TL may be made of a transparent resin material having refractive index that is lower (e.g., less) than the refractive index of the micro lens LN. As the top layer TL is in contact with the micro lens LN, due to the difference in refractive index at the interface between the lens layer 660 and the top layer TL, the light emitted from the emission layer EL and passing through the interface may be spread in the viewing angle direction, thereby ensuring a wide viewing angle. That is, at the interface between the top layer TL and the lens layer 660, the light concentrated by the micro lens LN may be diffused, thereby providing evenly distributed luminance over the entire area of the display device and at the same time providing a wide viewing angle.

The light emitting display device according to the second embodiment may provide high brightness with lower power consumption, due to the micro lens LN, by minimizing or at least reducing loss of light emitted from the emission layer EL and concentrating light into the central area direction. In addition, due to the flat surface 661 of the micro lens LN and the top layer TL disposed on the micro lens LN, the concentrated light into the central area may be diverted to a wide viewing angle, so that wide viewing angle may be ensured and luminance may be evenly distributed.

### Third Embodiment

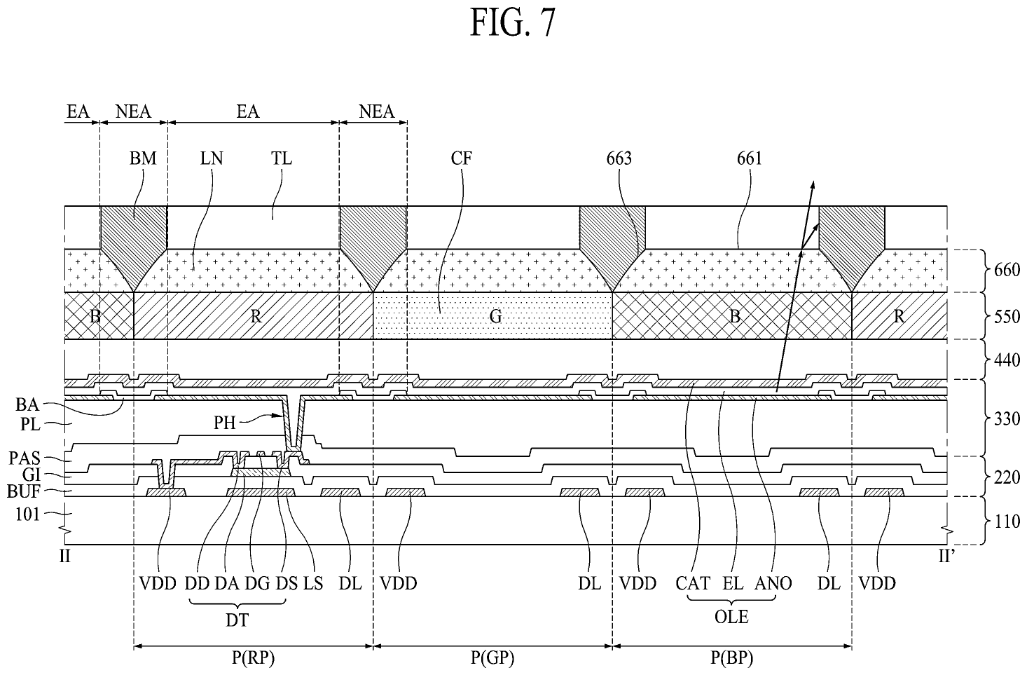

Hereinafter, referring to FIG. 7, a structure of a light emitting display device according to a third embodiment of the present disclosure will be explained. FIG. 7 is an enlarged cross-sectional view, cutting along line II-II′ of FIG. 3, for illustrating a structure of three pixels sequentially arrayed in a light emitting display device according to a third embodiment of the present disclosure.

A light emitting display device according to a third embodiment of the present disclosure shown in FIG. 7 may be very similar structure with that of the second embodiment. One of the features of the third embodiment is that the black matrix BM may penetrate through the entire thickness of the top layer TL, and extend up to the upper surface of the top layer TL. Thus, an upper surface of the black matrix BM is planar (e.g., aligned) with an upper surface of the top layer TL. The elements same with the second embodiment may not be duplicately explained.

The top layer TL may be disposed over entire surface of the substrate 110 on the lens layer 660 including the micro lenses LN. In one embodiment, the top layer TL may be made of a transparent material having a refractive index that is different from a refractive index of the micro lens LN. In particular, the top layer TL may be made of a transparent resin material having a refractive index that is lower than refractive index of the micro lens LN. As a result, light concentrated by the micro lens LN may be spread by the top layer TL, so the luminance may be evenly distributed over entire area of the display device, and wide viewing angle may be provided.

The black matrix BM may be disposed between a pair of neighboring micro lenses LN. The black matrix BM may have a structure in which it is vertically extended from the micro lens LN up to the upper surface of the top layer TL after penetrating the top layer TL. By this structure, light spread at the interface between the micro lens LN and the top layer TL may be prevented from being mixed at the boundary area between the neighboring pixels P. That is, evenly distributed luminance may be ensured, and clear color gamut may be acquired by preventing the color mixture.

In order to form the black matrix BM having the structure shown in FIG. 3, after forming the lens layer 660 including the black matrix BM and the micro lens LN, the top layer TL may be deposited, and then the portion corresponding to the black matrix BM is removed, and a black resin material may be additionally filled into the removed area. For another method, the micro lens LN is formed firstly, the top layer TL is deposited on the micro lens LN, a portion of the top layer TL corresponding to the black matrix BM is removed, and the black resin material is filled into the removed portion of the top layer TL.

The light emitting display device according to the third embodiment may provide high luminance with low power consumption by minimizing or at least reducing loss of light from the emission layer EL and concentrating light into the central area, by adapting the micro lens LN. Further, applying a flat surface at the central area of the micro lens LN and the top layer TL on the micro lens LN, the light may be not concentrated excessively in the central area, and may be diffused in the viewing angle direction, so a wide viewing angle and evenly distributed luminance may be provided. In addition, the black matrix BM may prevent or at least reduce the light passing through the lens layer 660 from being mixed at the boundary between the red pixel RP and the green pixel GP and the boundary between the green pixel GP and the blue pixel BP, so clearer image quality may be provided.

### Fourth Embodiment

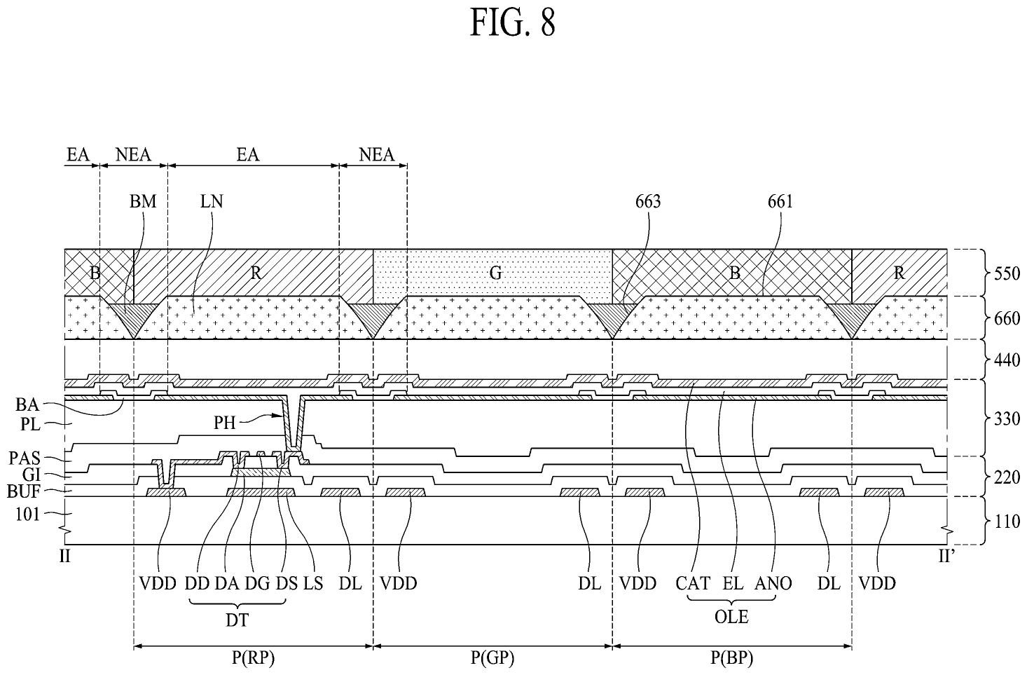

Hereinafter, referring to FIG. 8, a structure of a light emitting display device according to a fourth embodiment of the present disclosure will be explained. FIG. 8 is an enlarged cross-sectional view, cutting along line II-II′ of FIG. 3, for illustrating a structure of three pixels sequentially arrayed in a light emitting display device according to a fourth embodiment of the present disclosure. In FIG. 8, the elements below the encapsulation layer 440 may be same as described with FIG. 4, so the same explanation may not be duplicated, or simply described.

Referring to FIG. 8, the lens layer 660 may be disposed on the encapsulation layer 440. The lens layer 660 may include a plurality of micro lens LN and a black matrix BM surrounding each micro lens LN and connected as one grid shape. Each micro lens LN may be arranged in one-to-one correspondence with each pixel P. Each micro lens may include a flat surface 661 at the central area and a curved surface 663 at the edge area surrounding the flat surface 661. The flat surface 661 may have a size that is slightly larger or smaller than the anode electrode ANO. In some cases, the flat surface 661 may have the same size as the anode electrode ANO.

The curved surface 663 may be an area corresponding to the bank BA. At an area where two neighboring micro lenses LN meet or abut, two curved surfaces 663 of two neighboring micro lenses LS may be disposed to correspond to the bank BA.

The two curved surfaces 663 of the pair neighboring micro lenses LN may have a wedge shape or valley shape, such as ‘V’ shape. The black matrix BM may be disposed as corresponding to this ‘V’ shaped area. The black matrix BM may have the same size as the bank BA. Otherwise, the black matrix BM may have slightly smaller size than the blank BA, and be arranged to overlap the inside of the bank BA. The black matrix BM may prevent color mixing between two neighboring pixels P, that is, between the red pixel RP and the green pixel GP and between the green pixel GP and the blue pixel BP.

A color filter layer 550 may be disposed on the upper surface of the lens layer 660. The color filter layer 550 may include a plurality of color filters CF. For example, the color filter layer 550 may include a red color filter R, a green color filter G and a blue color filter B.

Even though it is not shown in figures, a capping layer made of a transparent resin material may be further disposed on the color filter layer 550. The capping layer may have a refractive index lower than a refractive index of the micro lens LN and/or the color filter CF of the color filter layer 550.

The light emitting display device according to the fourth embodiment may have a structure in which micro lenses LN may be arranged one-to-one in correspondence to the pixels P. Accordingly, the light provided from the emission layer EL of each pixel P may be concentrated to the central area of the pixel P by the micro lens LN, thereby improving the light emission efficiency. In addition, the micro lens LN of the display device according to the fourth embodiment may include a flat surface 661 at the central area. At the flat surface 661, the light provided from the emission layer EL may be not excessively concentrated but is emitted having a certain viewing angle. Further, the curved surface 663 may be disposed as surrounding the flat surface 661. At the curved surface 663, the light provided from the emission layer EL may be not lost by being absorbed by the black matrix BM placed at circumferential area of the pixel P, but be concentrated or re-directed to the central area of the pixel P.

The light emitting display device according to the fourth embodiment may retrieve or recover the amount of lost of light emitted from each pixel P to the central area, thereby minimizing or at least reduce the light loss and improving the light extraction efficiency. In addition, it may provide uniform luminance across a wide viewing angle direction. As a result, the fourth embodiment of the present disclosure may provide a display device that may provide a high luminance with low power consumption, and in which the distribution of luminance may be uniformly distributed over the entire area of the display device.

### Fifth Embodiment

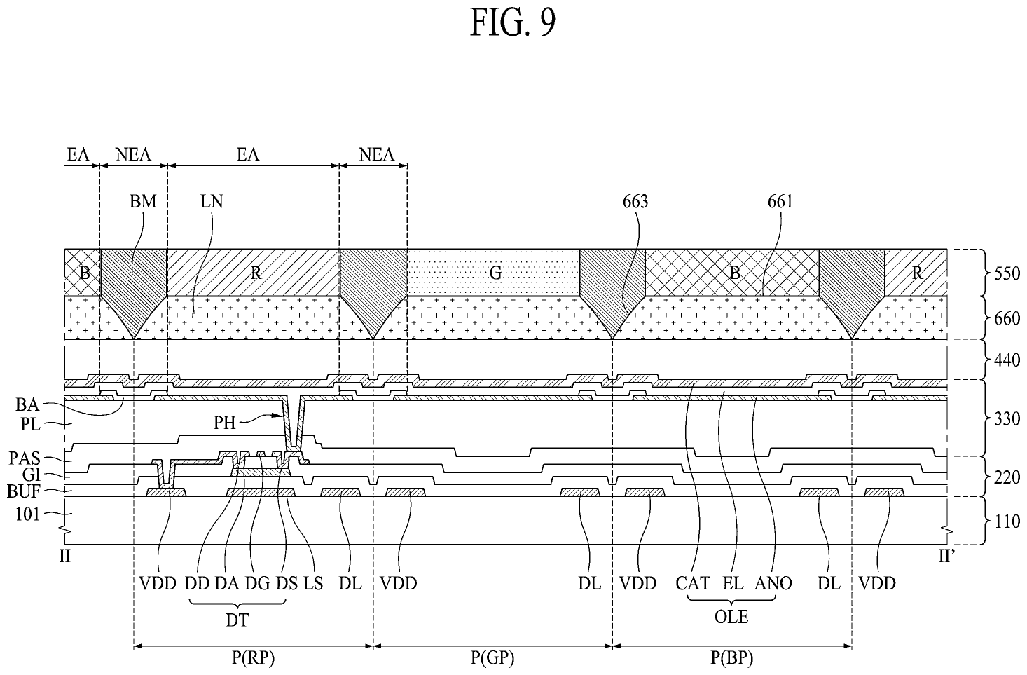

Hereinafter, referring to FIG. 9, a structure of a light emitting display according to a fifth embodiment of the present disclosure will be explained. FIG. 9 is an enlarged cross-sectional view, cutting along line II-II′ of FIG. 3, for illustrating a structure of three pixels sequentially arrayed in a light emitting display device according to a fifth embodiment of the present disclosure.

A light emitting display device according to a fifth embodiment of the present disclosure may have very similar structure as the fourth embodiment. The light emitting display device according to the fifth embodiment may have a structure in which the black matrix BM may penetrate through the entire thickness of the color filter layer 550 and be extended vertically from the micro lens LN to the upper surface of the color filter layer 550.

After forming the micro lens LN on the encapsulation layer 440, the color filter layer 550 may be deposited thereon. Then, the color filter layer 550 may be patterned to expose the curved surface 663 of the micro lens LN which is corresponding to the bank BA. The space between the patterned color filter layers 550, i.e., between the two curved surfaces 663 of the neighboring two micro lenses LN, may be filled with a black resin material to form a black matrix BM.

Even though it is not shown in figures, a capping layer made of a transparent resin material may be further disposed on the color filter layer 550. The capping layer may have a refractive index that is lower than the micro lens LN and/or the color filter CF of the color filter layer 550. In this case, the black matrix BM may be extended vertically from the lens layer 660, penetrate the color filter layer 550 and the capping layer, be stacked up to the upper surface of the capping layer.

The light emitting display device according to the fifth embodiment may provide high luminance with low power consumption by minimizing loss of light emitted from the emission layer EL due to the micro lens LB and by concentrating light into the central area. In addition, due to the flat surface 661 of the micro lens LN, the light may be not excessively concentrated in the central area and luminance may be evenly distributed. Furthermore, since the black matrix BM may be extended to the color filter layer 550, the light passing through the lens layer 660 may be prevented from being mixed at the boundary of the pixel P, thereby providing clearer image quality.

### Sixth Embodiment

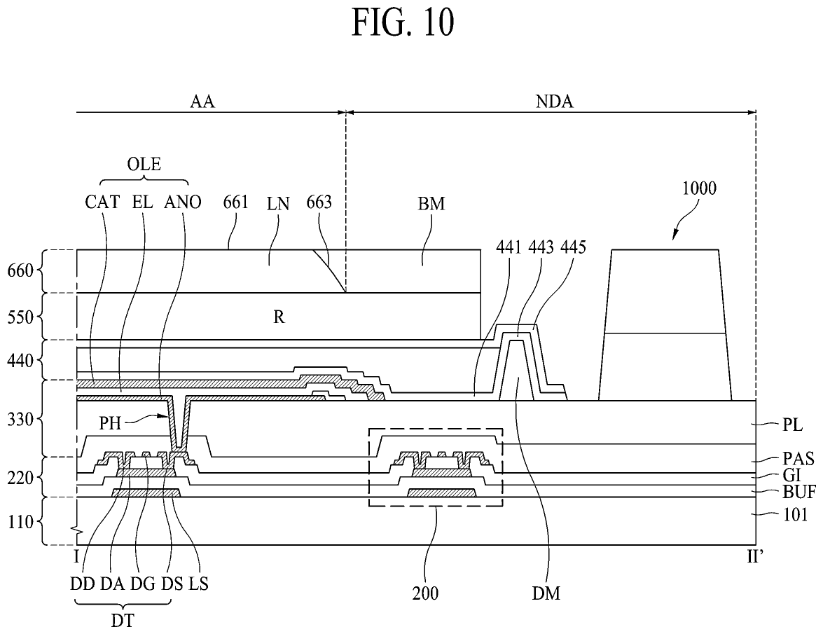

Hereinafter, referring to FIG. 10, a lens processing pattern 1000 in the light emitting display device according to one or more embodiments of the present disclosure will be explained. FIG. 10 is an enlarged cross-sectional view, cutting along line III-III′ of FIG. 1, for illustrating a portion where the lens processing pattern is formed in a light emitting display device according to one or more embodiments of the present disclosure.

In the above embodiments, various arrangement structures of the color filter layer 550 and the lens layer 660 disposed in the display area AA have been examined. In particular, the lens layer 660 may have a flat surface 661 in the central area, and may have a structure that may prevent the problem of excessive concentration of light by the lens layer 660 to the central area.

Hereinafter, elements and manufacturing process for forming the flat surface 661 to the micro lens LN of the lens layer 660 will be explained. As shown in FIG. 1, a lens processing pattern 1000 may be arranged around the display area AA to surround the display area AA.

Referring to FIG. 10, a cross-sectional view cutting along line III-III′ in FIG. 1, a light emitting display device according to the present disclosure may comprise the driving element layer 220, the light emitting element layer 330, the encapsulation layer 440, the color filter layer 550 and the lens layer 660, disposed sequentially on the substrate 110. A driving thin film transistor DT of the driving element layer 220 and the light emitting element layer 330 (specifically, a light emitting diode OLE of the light emitting element layer 330) may be disposed in the display area AA. Since the description of these elements may be the same as FIGS. 1 to 4, the same description may be not duplicated.

The gate driver 200 and the lens processing pattern 1000 may be disposed in the non-display area NDA. The gate driver 200 may have a structure same as the driving thin film transistor DT formed at the driving element layer 220. The lens processing pattern 1000 may be disposed outside of the gate driver 200.

Referring to FIG. 10, a dam DM may be further disposed at the edge area of the encapsulation layer 440. When the encapsulation layer 440 may include a first inorganic layer 441, an organic layer 443 and a second inorganic layer 445, the dam DM may be an element for being configured to limit the disposing area of the organic layer 443 from exceeding a specific area. In FIG. 10, the dam DM may be disposed outside of the gate driver 200. However, it is not limited thereto, the dam DM may be disposed closer to the display area AA than the gate driver 200.

For an example, the lens processing pattern 1000 may be arranged as overlapping the gate driver 200. In another example, the lens processing pattern 1000 may be disposed between the gate driver 200 and the dam DM. When the lens processing pattern 1000 is disposed outside of the gate driver 200, the bezel area may be minimized.

The lens processing pattern 1000 may be formed by stacking a plurality of layers, or may be formed as a single material layer. For an example, the lens processing pattern 1000 may be formed by stacking the dam DM, the color filter layer 550 and/or photo-resist materials used for the color filter layer 550. In another example, the lens processing pattern 1000 may be made of a non-conductive resin material different from material for elements of the display device.

A height of the upper surface of the lens processing pattern 1000 may be set to be the same as the height of the flat surface 661 of the micro lens LN. Thus, the upper surface of the lens processing pattern 1000 and the flat surface 661 of the micro lens LN are aligned or planar with each other. For example, after forming a micro lens LN having hemispherical shape, the convex surface of the micro lens LN may be formed into the flat surface 661 by pushing and/or rolling the hemispherical micro lens LN with a compression apparatus such as a roll to contact the lens processing pattern 1000.

By forming the height of the upper surface of the lens processing pattern 1000 disposed in the non-display area NDA to match the height of the flat surface 661 of the micro lens LN, and by applying a compression process using the lens processing pattern 1000, the micro lenses LN disposed over entire area of the display area AA may be formed to have the flat surfaces 661 at the same time. Therefore, uniform luminance with wide viewing angle may be provided throughout the entire area of the display area AA.

The height of the lens processing pattern 1000 may decide the height of the flat surface 661 of the micro lens LN. Therefore, in each of the first to fifth embodiments, the lens processing pattern 1000 is formed to have a height that matches the height of the flat surface 661 of the micro lens LN. In an example, for the first embodiment in which the lens layer 660 is disposed on the color filter layer 550, the height of the lens processing pattern 1000 may be set to be higher than the height of the lens processing pattern 1000 according to the fourth embodiment in which the lens layer 660 is disposed below the color filter layer 550.

### Seventh Embodiment

Hereinafter, referring to FIG. 11, a structure of a light emitting display device according to a seventh embodiment of the present disclosure. FIG. 11 is an enlarged cross-sectional view, enlarging ‘A’ portion of FIG. 1, for illustrating an example embodiment of the lens processing pattern in one or more embodiments of the present disclosure.

The lens processing pattern 1000 according to one or more embodiments of the present disclosure may have a closed curve shape surrounding the display area AA. In detail, the lens processing pattern 1000 may have a rectangular strip shape with a certain width W. Referring to FIG. 1, FIG. 10 and FIG. 11, the lens processing pattern 1000 may have a shape surrounding four sides of the display area AA.

However, it is not limited thereto, the lens processing pattern 1000 may be disposed at any opposing two sides. Otherwise, the lens processing pattern 1000 may be disposed at three sides around the display area AA. For example, in FIG. 1, except the side where the pad part 300 is disposed, the lens processing pattern 1000 may be arranged in a ‘∩’ shape or a ‘∩’ shape around the display area AA.

### Eighth Embodiment

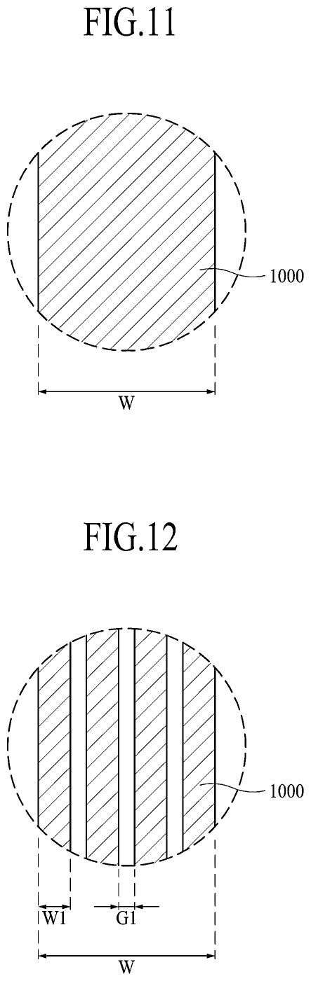

Hereinafter, referring to FIG. 12, a structure of a light emitting display according to an eighth embodiment of the present disclosure will be explained. FIG. 12 is an enlarged cross-sectional view, enlarging ‘A’ portion of FIG. 1, for illustrating another example embodiment of the lens processing pattern in one or more embodiments of the present disclosure.

The lens processing pattern 1000 according to eighth embodiment of the present disclosure may have a closed curve shape surrounding the display area AA. In detail, within a rectangular strip-shaped area having a total width W, a plurality of rectangular strips having a smaller width that the total width W, respectively, may be arranged at regular intervals or predetermined gaps. For example, as shown in FIG. 12, four closed curve shapes having a first width W1, respectively, may be arranged continuously and spaced apart at a first gap G1.

When a plurality of closed curve shapes is arranged in succession, even though one closed curve shape is damaged, the press for forming the flat surface 661 of the micro lens LN may maintain the height of the lens processing pattern 1000. While doing so, the height of the micro lens LN disposed in the display area AA may be processed to have uniform height. In addition, even though foreign matters may be generated during the lens processing step, the foreign matters may be inserted into the space having the first gap G1, thereby preventing damages caused by the foreign matters.

### Ninth Embodiment

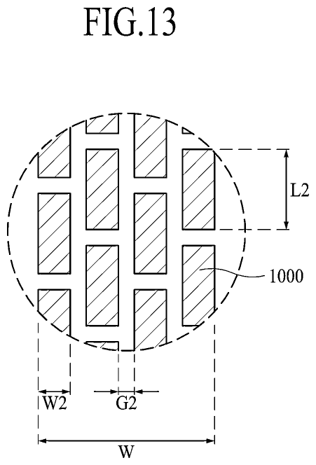

Hereinafter, referring to FIG. 13, a structure of a light emitting display device according to a ninth embodiment of the present disclosure will be explained. FIG. 13 is an enlarged cross-sectional view, enlarging ‘A’ portion of FIG. 1, for illustrating still another example embodiment of the lens processing pattern in one or more embodiments of the present disclosure.

The lens processing pattern 1000 according to ninth embodiment of the present disclosure may have a closed curve shape surrounding the display area AA. In detail, within a rectangular strip-shaped area having a total width W, a plurality of line segment shapes with smaller widths than the total width W and smaller lengths than the total length of the lens processing pattern 1000 may be placed at regular intervals or gaps. As shown in FIG. 13, a plurality of line segment shapes having a second width W2 and a second length L2 may be arranged continuously and spaced apart from each other at a second gap G2. In this case, the plurality of line segment shapes may be spaced apart at the same interval as the second gap G2 in the longitudinal direction of the segments. However, it is not limited thereto, the gap along the longitudinal direction may be wider or narrower than the second gap G2.

When a plurality of segments is arranged in succession, even though one closed curve shape is damaged, the press for forming the flat surface 661 of the micro lens LN may maintain the height of the lens processing pattern 1000. While doing so, the height of the micro lens LN disposed in the display area AA may be processed to have uniform height. In addition, even though foreign matters may be generated during the lens processing step, the foreign matters may be inserted into the space having the second gap G2, thereby preventing damages caused by the foreign matters.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. A light emitting display device comprising:
a substrate including a display area and a non-display area;
a plurality of pixels in the display area;
a lens processing pattern in the non-display area, the lens processing pattern surrounding the display area;
a light emitting element layer in the display area, the light emitting element layer configured to emit light;
an encapsulation layer on the light emitting element layer in the display area; and
a color filter layer and a lens layer on the encapsulation layer in the display area,
wherein a height of an upper surface of the lens processing pattern is a same as a height as an upper surface of the lens layer.

2. The light emitting display device according to claim 1, wherein the color filter layer is on the encapsulation layer and the lens layer is on the color filter layer such that the color filter layer is between the lens layer and the encapsulation layer.

3. The light emitting display device according to claim 1, wherein the lens layer is on the encapsulation layer and the color filter layer is on the lens layer such that the lens layer is between the color filter layer and the encapsulation layer.

4. The light emitting display device according to claim 1, wherein the lens layer includes a plurality of micro lenses, each of the plurality of micro lenses overlapping a corresponding one of the plurality of pixels.

5. The light emitting display device according to claim 4, wherein each of the plurality of micro lenses includes:
a flat upper surface that overlaps a central area of the pixel; and
a curved side surface that extends from the flat upper surface, the curved side surface overlapping an edge area of the pixel.

6. The light emitting display device according to claim 5, wherein a height of the flat upper surface of each of the plurality of micro lenses is a same as the height of the upper surface of the lens processing pattern.

7. The light emitting display device according to claim 1, wherein the light emitting element layer includes:
a planarization layer covering the substrate;
a plurality of anode electrodes on the planarization layer, each of the plurality of anode electrodes at a corresponding one pixel from the plurality of pixels;
a bank exposing a portion of each of the plurality of anode electrodes and covering a circumferential area of each of the plurality of anode electrodes;
an emission layer on the plurality of anode electrodes and the bank; and
a cathode electrode on the emission layer,
wherein the lens layer includes:
a plurality of micro lenses, each micro lens overlapping a corresponding pixel from the plurality of pixels; and
a black matrix between a pair of neighboring micro lenses from the plurality of micro lenses, the black matrix overlapping the bank, and
wherein each of the plurality of micro lenses includes:
a flat upper surface that overlaps a central area of a corresponding one anode electrode from the plurality of anode electrodes; and
a curved side surface that extends from the flat upper surface, the curved side surface overlapping the bank.

8. The light emitting display device according to claim 7, wherein the black matrix overlaps curved side surfaces of a pair of neighboring micro lenses from the plurality of micro lenses.

9. The light emitting display device according to claim 7, wherein the color filter layer is on the encapsulation layer and the lens layer is on the color filter layer such that the color filter layer is between the lens layer and the encapsulation layer.

10. The light emitting display device according to claim 9, further comprising:
a capping layer on the lens layer, the capping layer including a transparent material having a refractive index that is less than a refractive index of the plurality of micro lenses.

11. The light emitting display device according to claim 10, wherein the black matrix extends to an upper surface of the capping layer through an entire thickness of the capping layer.

12. The light emitting display device according to claim 7, wherein the lens layer is on the encapsulation layer and the color filter layer is on the lens layer such that the lens layer is between the color filter layer and the encapsulation layer.

13. The light emitting display device according to claim 12, wherein the black matrix extends to an upper surface of the color filter layer through an entire thickness of the color filter layer.

14. The light emitting display device according to claim 12, further comprising:
a capping layer on the color filter layer, the capping layer including a transparent material having a refractive index that is less than a refractive index of the plurality of micro lenses.

15. The light emitting display device according to claim 14, wherein the black matrix extends to an upper surface of the capping layer through an entire thickness of the color filter layer and an entire thickness of the capping layer.

16. The light emitting display device according to claim 1, wherein the lens processing pattern includes a closed curved shape that surrounds the display area, the closed curved shape having a width.

17. The light emitting display device according to claim 1, wherein the lens processing pattern includes a plurality of closed curved shapes that each have a predetermined width and the plurality of closed curved shapes are spaced apart from each other at a predetermined gap between a pair of closed curved shapes from the plurality of closed curved shapes.

18. The light emitting display device according to claim 1, wherein the lens processing pattern includes a plurality of segments that each have a predetermined width and a predetermined length, and the plurality of segments are spaced apart from each other at a predetermined gap between a pair of segments from the plurality of segments.

19. The light emitting display device according to claim 1, further comprising:
a driving element layer between the substrate and the light emitting element layer in the display area, the driving element layer configured to drive the light emitting element layer.

20. A display device comprising:
a substrate including a display area and a non-display area;
a transistor on the display area of the substrate;
a planarization layer on the display area and the non-display area, the planarization layer on the transistor in the display area;
a light emitting element configured to emit light in an emission area of the light emitting element, the light emitting element on the planarization layer and connected to the transistor;
an encapsulation layer on the light emitting element in the display area;
a color filter overlapping the emission area of the light emitting element; and
a lens overlapping the color filter and the emission area of the light emitting element, the lens having a flat upper surface and a curved side surface that extends from the flat upper surface.

21. The display device of claim 20, further comprising:
a lens processing pattern in the non-display area, the lens processing pattern surrounding the display area,
wherein a height of an upper surface of the lens processing pattern is a same as a height as the flat upper surface of the lens.

22. The display device of claim 20, wherein the color filter is between the lens and the encapsulation layer.

23. The display device of claim 20, wherein the lens is between the color filter and the encapsulation layer.

24. The display device of claim 20, further comprising:
another lens that neighbors the lens, the other lens having a flat upper surface of the other lens and a curved side surface of the other lens that extends from the flat upper surface of the other lens; and
a black matrix between and in contact with the curved side surface of the lens and the curved side surface of the other lens.

25. The display device of claim 20, further comprising:
a capping layer over the lens and the color filter, the capping layer including a transparent material having a refractive index that is less than a refractive index of the lens.
